(19) United States
(12) Patent Application Publication
(10) Pub. No.: US 2026/0299026 A1
(43) Pub. Date: Oct. 1, 2026

(54) SYSTEM AND METHOD FOR INTELLIGENT DIAGNOSTICS AND MONITORING FOR A BATTERY ENERGY STORAGE SYSTEM

(71) Applicant: Fluence Energy, LLC, Arlington, VA (US)

(72) Inventors: Mohamamdhassan Abdollahi Sofla, Raleigh, NC (US); Isaiah Dallas Jefferson, Jr., Mitchellville, MD (US)

(73) Assignee: Fluence Energy, LLC, Arlington, VA (US)

(21) Appl. No.: 18/874,357

(22) PCT Filed: Sep. 27, 2024
(86) PCT No.: PCT/US2024/048787

§ 371 Date: Dec. 12, 2024

Related U.S. Application Data
(60) Provisional application No. 63/541,460, filed on Sep. 29, 2023.

(51) Int. Cl. G01R 31/367; G01R 31/371; G01R 31/392; G08B 21/18; H01M 50/251

(52) U.S. Cl. CPC G01R 31/367; G01R 31/371; G01R 31/392; G08B 21/185; H01M 50/251

(57) ABSTRACT

A system includes an energy storage system includes a plurality of energy storage nodes and an intelligent diagnostics and monitoring (“IDM”) module coupled to the energy storage system. The IDM module includes a processor that monitors control signals of the energy storage system and enters a multi-stage diagnostic process including detecting shallow errors, faults, or abnormalities based on the monitored control signals, starting a root-cause analysis (RCA) algorithm when shallow errors, faults, or abnormalities are detected, starting a deep diagnostic algorithm when no shallow errors, faults, or abnormalities are detected, after starting the deep diagnostic algorithm, detecting errors, faults, or abnormalities based on the monitored control signals, and troubleshoot the energy storage system when errors, faults, or abnormalities are detected.

### CROSS-REFERENCE TO RELATED APPLICATIONS

This application claims priority to U.S. Patent Application No. 63/541,460 filed on Sep. 29, 2023, titled “System and Method for Intelligent Monitoring and Diagnostics for a Battery Energy Storage System,” the content of which is hereby incorporated by reference in its entirety.

### TECHNICAL FIELD

The present disclosure relates to systems and methods for automatically diagnosing and monitoring a battery energy storage system (BESS).

### BACKGROUND

Battery energy storage systems, compound energy storage systems, as well as some energy provisioning systems, are highly complex systems with a large number of interrelated components. The performance of any individual sub-component can affect the performance of a large number of other components. For example, a single poorly performing kilowatt battery cell can reduce the overall performance of all of the other battery cells in a multi-terawatt battery energy storage system. Therefore, proper initial configuring, as well as finding and resolving issues (“debugging”) during operation is of critical importance. Configuring and finding, then resolving, issues quickly is paramount to running an energy provisioning system in an economical manner.

However, current manual debugging and troubleshooting in all phases of an energy provisioning system lifecycle creates considerable delays impacting the site reliability. During deployment and operation, the site of the energy provisioning system can have faults. Since energy provisioning systems are very complex, diagnosing failure of these complex energy provisioning systems is time consuming. During deployment of energy provisioning systems, time-consuming diagnostic processes can cause delays and result in overrun fees and monetary fines.

During operation of an energy provisioning system, failures can lower availability of the energy provisioning system site and even cause costly damages to the energy provisioning system or connected loads, such as an electrical grid, for example. Currently, substantial labor hours are spent in troubleshooting failures on sites. In addition, the revenue generated by an energy provisioning system is directly related to the availability of the sites, and these sites are impacted by lengthy troubleshooting processes.

Hence, there is a need for systems and methods to monitor and automatically diagnose a battery energy storage system.

### SUMMARY

In a first example, a system 100 includes an energy storage system 101 including a plurality of energy storage nodes 105A-N, and an intelligent diagnostics and monitoring (“IDM”) module 502 coupled to the energy storage system 101 and including a processor 312, 352. The IDM module 502 is configured to: monitor control signals of the energy storage system 101; and enter a multi-stage diagnostic process including: detecting shallow errors, faults, or abnormalities based on the monitored control signals; starting a root-cause analysis (RCA) algorithm when shallow errors, faults, or abnormalities are detected; starting a deep diagnostic algorithm when no shallow errors, faults, or abnormalities are detected; after starting the deep diagnostic algorithm, detecting errors, faults, or abnormalities based on the monitored control signals; and troubleshoot the energy storage system 101 when errors, faults, or abnormalities are detected.

In a second example, a method includes detecting shallow abnormalities of an energy storage system 101; starting a root-cause analysis (RCA) algorithm when shallow abnormalities are detected; starting a deep diagnostic algorithm when no shallow abnormalities are detected; after starting the deep diagnostic algorithm, detecting abnormalities based on the monitored control signals; and troubleshooting the energy storage system 101 when abnormalities are detected.

In a third example, a non-transitory computer-readable medium 313 includes an intelligent diagnostics and monitoring (“IDM”) module 502. Execution of the IDM module 502 by one or more processors 312 configures one or more computing devices to: detect shallow abnormalities of an energy storage system 101; start a root-cause analysis (RCA) algorithm when shallow abnormalities are detected; start a deep diagnostic algorithm when no shallow abnormalities are detected; after starting the deep diagnostic algorithm, detect abnormalities based on the monitored control signals; and troubleshoot the energy storage system 101 when abnormalities are detected.

Additional objects, advantages and novel features of the examples will be set forth in part in the description which follows, and in part will become apparent to those skilled in the art upon examination of the following and the accompanying drawings or may be learned by production or operation of the examples. The objects and advantages of the present subject matter may be realized and attained by means of the methodologies, instrumentalities and combinations particularly pointed out in the appended claims.

### BRIEF DESCRIPTION OF THE DRAWINGS

The drawing figures depict one or more implementations in accordance with the present concepts, by way of example only, not by way of limitations. In the figures, like reference numerals refer to the same or similar elements.

FIG. 1 depicts a system that includes an energy storage system, an energy system, and an electrical application, according to embodiments of the present disclosure.

FIG. 2 illustrates a first energy storage node of a plurality of energy storage nodes of the energy storage system of FIG. 1 coupled to the electrical application.

FIG. 3 is a cutaway view of the first energy storage node of the plurality of energy storage nodes and shows details of a plurality of battery storage elements.

FIG. 4 is a high-level functional block diagram of the energy storage system of FIG. 1 that depicts components of the control system and the energy storage nodes for automatically diagnosing and monitoring a battery energy storage system.

FIG. 5 is a diagram depicting an intelligent diagnostics and monitoring (“IDM”) in energy storage systems.

FIG. 6 is a diagram depicting an intelligent diagnostics and monitoring (“IDM”) module-logic for the deployment phase of an energy storage system.

FIG. 7 is a diagram depicting an intelligent diagnostics and monitoring (“IDM”) module-logic for the online mode of an energy storage system.

FIG. 8 is a diagram depicting an automated root cause analysis algorithm and final report generation based on that analysis.

Parts Listing

| | |
|---|---|
| 100 | System |
| 101 | Energy Storage System |
| 102 | Energy System |
| 103 | Electrical Application |
| 104 | Power Conversion System |
| 105A-N | Energy Storage Nodes |
| 106, 106A-N | Battery Storage Elements |
| 107 | Power Conversion Subsystem |
| 108 | Transformer |
| 109 | Energy Source |
| 110 | Control Subsystem |
| 111A-N | Electrical Data |
| 115 | Control System |
| 116A-N | Battery Data |
| 117A-N | Expected or Predetermined |
| | Values or Ranges |
| 120 | Physical Space |
| 125 | Power Bus |
| 205 | Power Inverter |
| 210 | Rectifier |
| 215 | DC-DC Converter |
| 300 | Enclosure |
| 305, 305A-N | Network |
| 311, 351 | Network Communication Interface |
| 312, 352 | Processor |
| 313, 353 | Memory |
| 315A-N | Sensors |
| 330A-B | Intelligent Diagnostics |
| | and Monitoring (“IDM”) |
| | Module Control Programming |
| 340A-B | Root-cause Analysis (“RCA”) |
| | Control Programming |
| 350A-B | Deep Diagnostic |
| | Control Programming |
| 370A-N | Environmental Sensors |
| 375A-N | Battery Sensors |
| 502 | Intelligent Diagnostics and |
| | Monitoring (“IDM”) Module |
| 504 | FOS controls |
| 506 | Battery Management |
| | System (“BMS”) |
| 508 | Meters |
| 510 | Switches |
| 512 | Real-time Automation |
| | Controller (“RTAC”) |
| 514 | User Interface |
| 516 | Data Acquisition System |
| 600 | Process Flow |
| 700 | Process Flow |
| 800 | Process Flow |

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, transfer functions, and/or circuitry have been described at a relatively high-level, without detail, in order to avoid unnecessarily obscuring aspects of the present teachings.

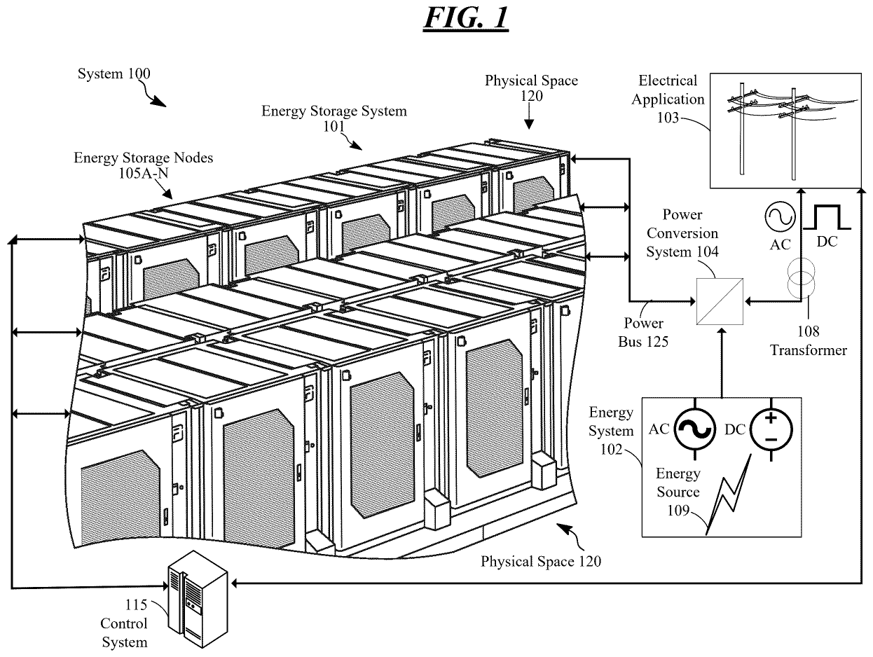

Unless otherwise indicated, any embodiment can be combined with any other embodiment. In particular, FIGS. 1-8 and the associated text are all combinable with each other.

The term “coupled” as used herein refers to any logical, physical, electrical, or optical connection, link or the like by which signals or light produced or supplied by one system element are imparted to another coupled element. Unless described otherwise, coupled elements or devices are not necessarily directly connected to one another and may be separated by intermediate components, elements, or communication media that may modify, manipulate, or carry the light or signals.

The orientations of the system 100, energy storage system 101, energy storage nodes 105A-N, associated components, and/or any complete devices, incorporating battery storage elements 106A-N, such as batteries, such as shown in any of the drawings, are given by way of example only, for illustration and discussion purposes. In operation for a particular energy storage application, an energy storage node 105A-N may be oriented in any other direction suitable to the particular application of the energy storage system 101, for example upright, sideways, or any other orientation. Also, to the extent used herein, any directional term, such as left, right, front, rear, back, end, up, down, upper, lower, top, bottom, and side, are used by way of example only, and are not limiting as to direction or orientation of any energy storage system 101 or energy storage nodes 105A-N; or component of an energy storage system 101 or energy storage nodes 105A-N constructed as otherwise described herein.

Unless otherwise indicated, any multiplicity of components, such as energy storage nodes 105A-N or battery storage elements 106A-N can include any number of said components, including as few as one, and are not limited by the depicted number of components. Unless otherwise indicated, any coupled electrical components can be linked in series or in parallel. In the case of energy storage nodes 105A-N or battery storage elements 106A-N, the components may be linked in series, in parallel, or a combination thereof depending upon a state of a switch or a submodule.

The intelligent diagnostics and monitoring technologies disclosed herein detect failures or faults and immediately perform a full analysis to find the root cause of the failure or fault, as well as create a report and alert a service team tasked with correcting failures and faults.

The intelligent diagnostics and monitoring technologies use an intelligent algorithm to create real-time diagnostics of the entire energy provisioning system or battery energy storage system (BESS). The intelligent diagnostics and monitoring technologies include two levels of diagnostics: deployment submodule technologies and operation submodule technologies.

In deployment submodule technologies, after the operating system (OS) which controls the entire BESS is deployed, the deployment submodule technologies run a full analysis of the signals, logs, and statuses of components and sub-components of the BESS and create a report of any issues. The deployment submodule technologies have two analyses levels: a logic state level and an online level.

In the logic state level, while the BESS is disconnected from the load or electrical grid, the deployment submodule technologies check all of the statuses, logs, and signals for abnormalities, interconnected issues, compatibility between components and sub-components, and failures. In the online level, the deployment submodule technologies will run automatic tests and analyze the responses for abnormalities and failures.

Operation submodule technologies run and monitor all available signals and detect failures.

These improvements to intelligent diagnostics and monitoring technologies can increase energy provisioning site availability, and remove at least a week of diagnostic time in deployment and operations lost to debugging and troubleshooting.

Reference now is made in detail to the examples illustrated in the accompanying drawings and discussed below.

FIG. 1 depicts a system 100 that includes an energy storage system 101, energy system 102, and an electrical application 103. For example, the energy storage system 101 can be a battery energy storage system (BESS). The energy storage system 101 is coupled to the energy system 102 and the electrical application 103. Energy storage system 101 can include a power conversion system 104, a plurality of energy storage nodes 105A-N, an optional transformer 108, and a control system 115. Components of the energy storage system 101 can be located at a physical space 120 that is outdoors or indoors, for example, inside of a building, a container, or other structure.

Power conversion system 104 is coupled to the plurality of energy storage nodes 105A-N. The power conversion system 104 is coupled to the energy system 102 and the electrical application 103 to provide a required power flow to the electrical application 103 by discharging the plurality of energy storage nodes 105A-N or the required power flow from the energy system 102 for charging the plurality of energy storage nodes 105A-N. The power conversion system 104 can be coupled to an optional transformer 108. The optional transformer 108 can step up or step down the required power flow to and from the electrical application 103, such as an AC voltage.

Energy system 102 can include any suitable system for producing electrical energy from an energy source 109. Energy system 102 can be a renewable energy system in which the energy source 109 can be replenished. Such a renewable energy source 109 can include solar power, wind power, geothermal power, biomass, and hydroelectric power. For example, the renewable energy system 102 can be implemented as an array of photovoltaic modules. The photovoltaic (PV) modules can include crystalline silicon, amorphous silicon, copper indium gallium selenide (CIGS) thin film, cadmium telluride (CdTe) thin film, and concentrating photovoltaic which uses lenses and curved mirrors to focus sunlight onto small, but highly efficient, multi-junction solar cells. In another example, the energy system 102 can include wind turbines or gas turbines. In some examples, the energy system 102 can be a non-renewable energy system in which the energy source 109 includes a non-renewable energy source, such as a fossil fuel.

Electrical application 103 can include an electrical grid, such as a power grid, or a smaller local load, such as a backup power system, for a facility such as a hospital, manufacturing site, residential home, or other suitable facility. The electrical application 103 may deliver AC or DC power for on-grid or off-grid applications, including commercial, industrial, or residential applications. The electrical application 103 may deliver power to buildings, electric vehicle charging stations, etc., including a variety of electrical loads that consume AC or DC electric power. The electrical application 103 can be a front-of-the-meter system that is owned or operated by a utility company or a behind-the-meter system that directly supplies buildings and homes with electricity.

Energy source 109 can be a renewable energy source, such as solar power and wind power, which can be intermittent and less reliable compared to fossil fuels. To improve resiliency, energy storage system 101 can store energy from the energy system 102 when the production from the energy source 109 is high. Later on, the energy storage system 101 can dispatch the energy to the electrical application 103 when demand is high or production from the energy source 109 is not keeping up with demand. Moreover, events may occur when a connected load or an operating demand load of the electrical application 103 is excessive or there is electrical grid instability, such as during extreme weather. By storing energy from the energy source 109 and then dispatching the energy during such events, the energy storage system 101 can continue to dispatch a required power flow of the electrical application 103.

Energy storage nodes 105A-N include battery storage elements 106A-N. The battery storage elements 106A-N can be: (1) a single battery cell; (2) a cell grouping, including several battery cells in parallel configuration; (3) a battery submodule or module, including several battery cells in parallel and serial configuration; (4) a battery string, including several battery modules in series; (5) a battery bank, including several battery strings in parallel; (6) other known energy storage elements; and/or (7) a combination thereof. For example, the battery storage elements 106A-N can include a plurality of batteries of any existing or future reusable battery technology that can be used in a battery energy storage system (BESS), including, but not limited to, lithium ion or flow batteries, or mechanical storage, such as flywheel energy storage, compressed air energy storage, pumped-storage hydroelectricity, gravitational potential energy, or a hydraulic accumulator, for example.

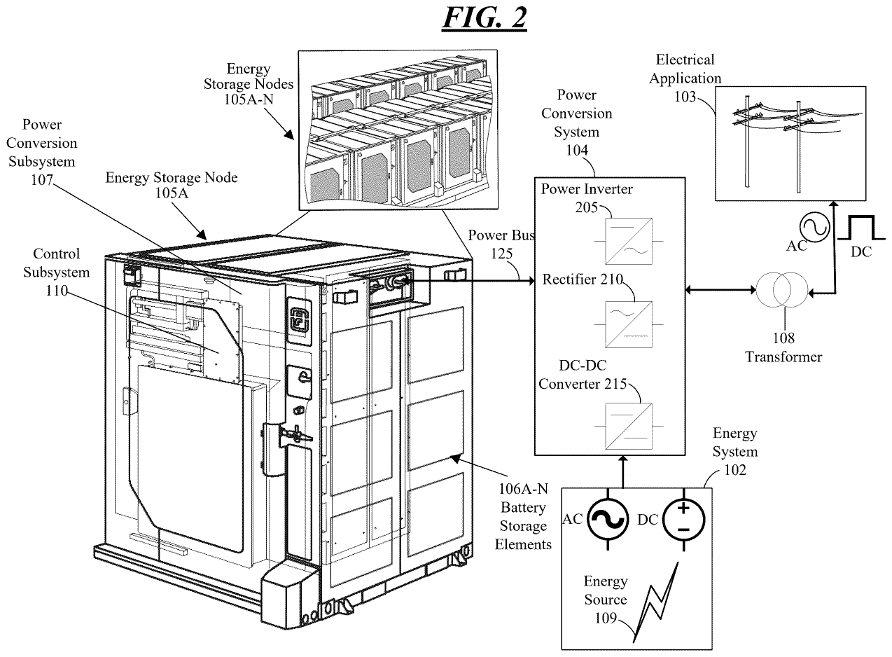

FIG. 2 illustrates a first energy storage node 105A of the plurality of energy storage nodes 105A-N of FIG. 1 coupled to the electrical application 103. Energy storage nodes 105A-N can include a battery storage element 106, a power conversion subsystem 107, and a control subsystem 110, or a combination thereof. Energy storage system 101 can be controlled such that the electrical application 103 is fulfilled while distributing the dispatch of required power flow across the plurality of battery storage elements 106A-N according to awareness of the control system 115 relating to certain battery conditions, including a state of charge, a temperature, and other physical phenomena occurring within the battery storage elements 106A-N.

Power conversion system 104 can include a power inverter 205, a rectifier 210, a DC-DC converter 215, other power conversion elements, or a combination thereof. Power inverter 205 can be configured to convert a DC source, such as from the battery storage elements 106A-N, into an AC waveform. Rectifier 210 can be configured to convert an AC source, such as from the energy system 102 or electrical application 103, into DC for the battery storage elements 106A-N. DC-DC converter 215 can be configured to convert a DC source, such as from the battery storage elements 106A-N, into a different DC source characteristic.

If the energy source 109 is wind power, then the power conversion system 104 can convert the AC electricity produced into DC power for storage in the plurality of energy storage nodes 105A-N via the rectifier 210. If the energy source 109 is solar power, then the power conversion system 104 can convert the DC electricity into a different voltage level via the DC-DC converter 215. The power inverter 205 can convert the required power flow from the energy storage system 101 from DC power into AC power during dispatch to the electrical application 103. For example, the power inverter 205 can be configured to convert power on a power bus 125 for use by the electrical application 103. For example, the power inverter 205 converts DC power stored in the energy storage nodes 105A-N into AC power for consumption by electrical loads of the electrical application 103.

Power conversion subsystem 107 includes similar hardware and software as the more centralized power conversion system 104. Power conversion subsystem 107 is distributed more locally to each of energy storage nodes 105A-N. The control subsystem 110 can be configured for local computation, processing, and control of the battery storage elements 106A-N and the power conversion subsystem 107. The control system 115 can be configured for more centralized computation, processing, and controls of the overall energy storage system 101, energy system 102, electrical application 103, and power conversion system 104. Both the control subsystem 110 and control system 115 can include a single board computer, an application-specific integrated circuit (ASIC), microcontroller, digital signal processor (DSP), field-programmable gate array (FPGA), or a combination thereof.

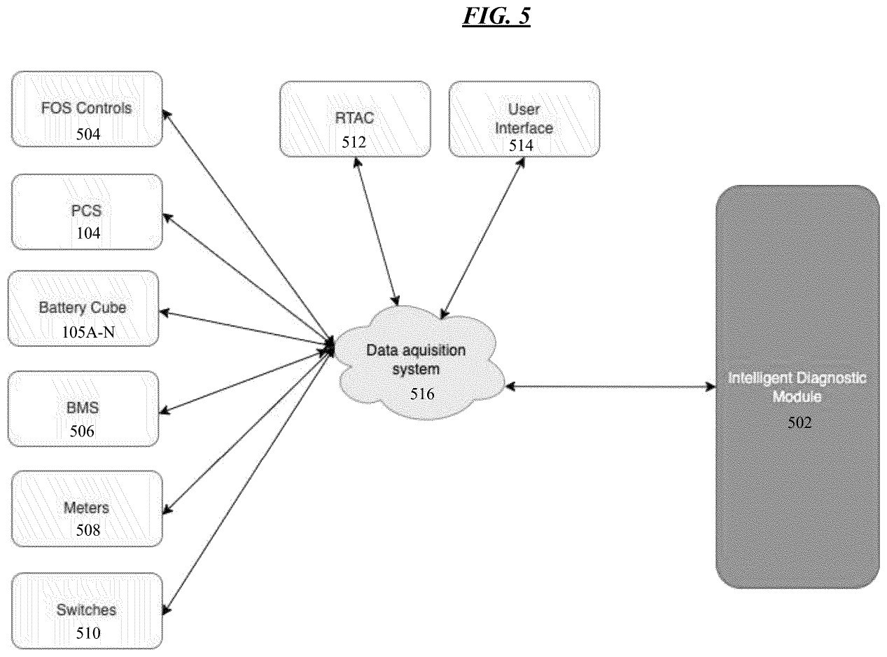

The control system 115 and the control subsystem 110 may interface with or include an intelligent diagnostics and monitoring (“IDM”) module 502 (see FIG. 5).

Physical data collection sensors and data logging can be used throughout the energy storage system 101, to collect operational and environmental data from the components of the energy storage system 101, such as the energy storage nodes 105A-N, PCSs, battery management systems (BMSs), apparent power system controllers (APSs), node storage dispatch units (SDUs), core SDUs, and real-time automation controllers (RTACs). The collected data can include, but is not limited to, state of charge (SOC), power, differential voltages, or temperature of the energy storage nodes, PCSs, BMSs, APSs, node SDUs, core SDUs, or RTAC.

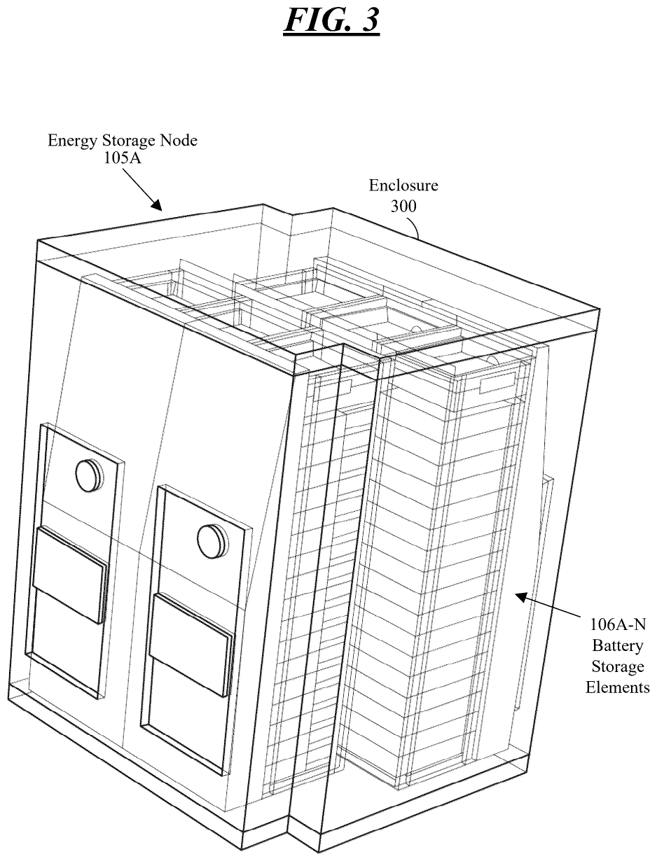

FIG. 3 is a cutaway view of the first energy storage node 105A of the plurality of energy storage nodes 105A-N and shows details of a plurality of battery storage elements 106A-N. As shown, the energy storage node 105A includes an enclosure 300, such as a physical housing to store a plurality of battery storage elements 106A-N. The battery storage elements 106A-N can be a collection of one or more batteries, such as a plurality of battery strings or battery banks, which are organized logically, physically, and electrically.

In the example of FIG. 3, the battery storage elements 106A-N can include battery racks (e.g., six are shown) that hold a respective stack of battery modules (e.g., seventeen are shown). The battery modules can include an array of prismatic, pouch, or cylindrical battery cells that are packaged together to increase voltage, amperage, or both. In some examples, battery modules may include an electric vehicle battery pack, e.g., a collection of lithium-ion battery cells that are packaged together.

The energy storage nodes 105A-N may resemble the features presented in the energy storage system described in International Application No. PCT/US2021/30551, filed on May 4, 2021, titled “Energy Storage System with Removable, Adjustable, and Lightweight Plenums,” the entirety of which is incorporated by reference herein.

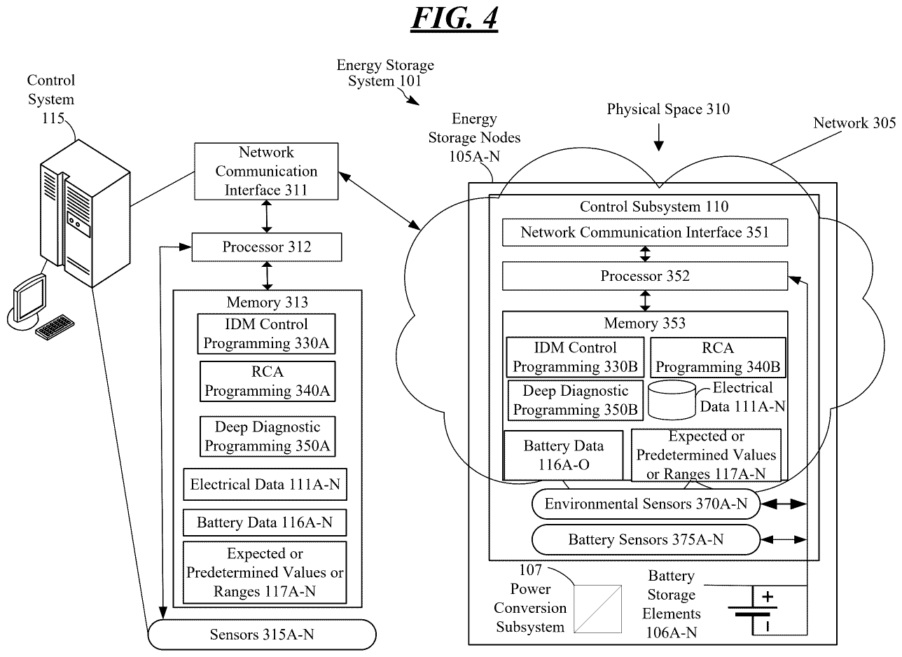

FIG. 4 is a high-level functional block diagram of the energy storage system 101 of FIG. 1 that depicts components of the control system 115 and the energy storage nodes 105A-N to automatically monitor and diagnose the energy storage system 101 based on control signals of the energy storage system 101. As shown, the plurality of energy storage nodes 105A-N include a battery storage element 106A-N, a power conversion subsystem 107, and a control subsystem 110 configured to receive battery data 116A-N and electrical data 111A-N from the battery storage element 106A-N, the power conversion subsystem 107, or a combination thereof.

The control signals of the energy storage system 101 can include, but are not limited to, operational data or electrical data 111A-N, such as current, voltage, power, charge or discharge commands, power pulse patterns during charging or discharging (e.g., activity pattern), apparent power or real time power (e.g., activity pattern) from the battery storage element 106A-N, the power conversion subsystem 107, or a combination thereof, and battery data 116A-N, such as battery voltage, battery current, battery temperature, battery state of charge (SOC), or other physical phenomena occurring within the battery storage elements 106A-N, and/or environmental data, in particular voltage, current, temperature, or state of charge from the components of the battery energy storage system, such as the power input and output of PCSs or battery management systems (BMSs), which, along with the PCSs, communicate with apparent power system controllers (APSs), full operating system (FOS) control signals, as well as feedback and statuses from a battery management system (BMS), the battery storage element 106A-N, power conversion system (PCS) 104, and meter subsystems. The APSs and the BMSs communicate with node storage dispatch units (SDUs). Node SDUs interface with and monitor the connected BMSs, PCSs and other hardware to higher level controls. The electrical data 111A-N can also include at least one of current and voltage or power output of the power conversion system 104.

The control system 115, energy storage nodes 105A-N, electrical application 103, and other components of the system 100 can be in communication over a network 305 or one or more networks 305A-N. The networks 305A-N can be a local area network 305A, wide area network 305B, or a combination thereof. For example, the control system 115 can be coupled via a local area network 305A to the energy storage nodes 105A-N and the electrical application 103. Alternative or additionally, the control system 115 can be coupled via a wide area network 305B to the energy storage nodes 105A-N and electrical application 103. Or the control system 115 can be coupled via a combination of networks 305A-N, such as via a local area network 305A to components of the energy storage system 101, including the energy storage nodes 105A-N, and coupled via a wide area network 305B to the electrical application 103.

Control system 115 includes a network communication interface 311 configured for wired or wireless communication over the network 305. The control system 115 further includes a memory 313, and a processor 312 coupled to the network communication interface 311 and the memory 313. As shown, the memory 313 of the control system 115 is configured to store an intelligent diagnostics and monitoring (“IDM”) module control programming 330A, a root-cause analysis (“RCA”) control programming 340A, a deep diagnostic control programming 350A, electrical data 111A-N, and battery data 116A-N. The control system 115 can also include sensors 315A-N coupled to the processor 312 to detect or monitor various system parameters, such as power, temperature, voltage, current, resistance, and/or impedance. For example, the sensors 315A-N can be coupled to the power bus 125.

Control system 115 is configured to store, e.g., in memory 313, expected or predetermined values or ranges 117A-N for the battery data 116A-N and electrical data 111A-N from the battery storage element 106A-N, the power conversion subsystem 107, or a combination thereof. Based on the result of the comparison of the values of the received battery data 116A-N and electrical data 111A-N from the battery storage element 106A-N, the power conversion subsystem 107, or a combination thereof, with the stored expected or predetermined values or ranges 117A-N for the battery data 116A-N and electrical data 111A-N, the control system 115 can detect errors, faults, or abnormalities based on the monitored control signals, as described further below. In the context of the present disclosure, errors, faults, or abnormalities relate to deviations or discrepancies from the expected behavior of the energy storage system 101, including but not limited to out of expected range values for measured parameters, malfunctioning of components, generation of errors or warnings, or any other unexpected behavior of the energy storage system 101.

Energy storage nodes 105A-N include a control subsystem 110, battery storage elements 106A-N, and a power conversion subsystem 107. Control subsystem 110 of the energy storage nodes 105A-N includes a network communication interface 351 configured for wired or wireless communication over the network 305. The control subsystem 110 further includes a memory 353, and a processor 352 coupled to the network communication interface 351 and the memory 353. As shown, the memory 353 of the control subsystem 110 can be configured to store an intelligent diagnostics and monitoring (“IDM”) module control programming 330B, a root-cause analysis (RCA) control programming 340B, a deep diagnostic control programming 350B, battery data 116A-N and electrical data 111A-N from the battery storage element 106A-N, the power conversion subsystem 107, or a combination thereof, and expected or predetermined values or ranges 117A-N for the battery data 116A-N and electrical data 111A-N.

The control subsystem 110 can further include environmental sensors 370A-N coupled to the processor 352. Environmental sensors 370A-N can measure humidity and temperature inside of an enclosure 300 of the energy storage nodes 105A-N.

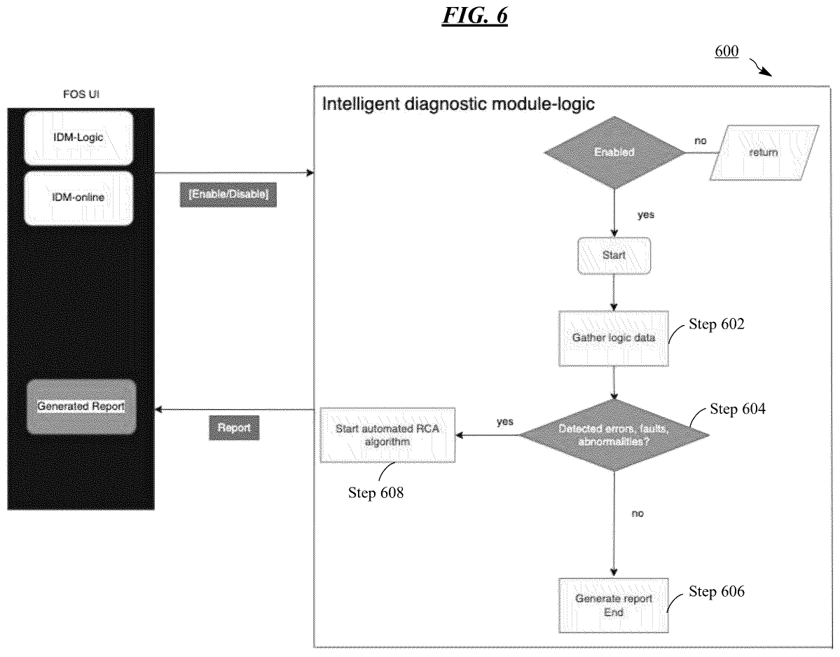

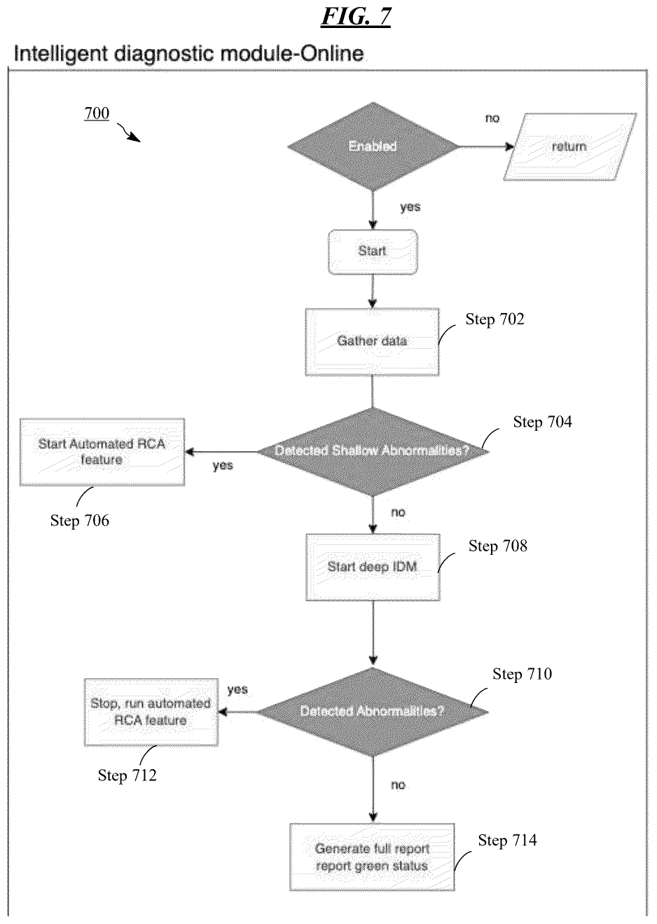

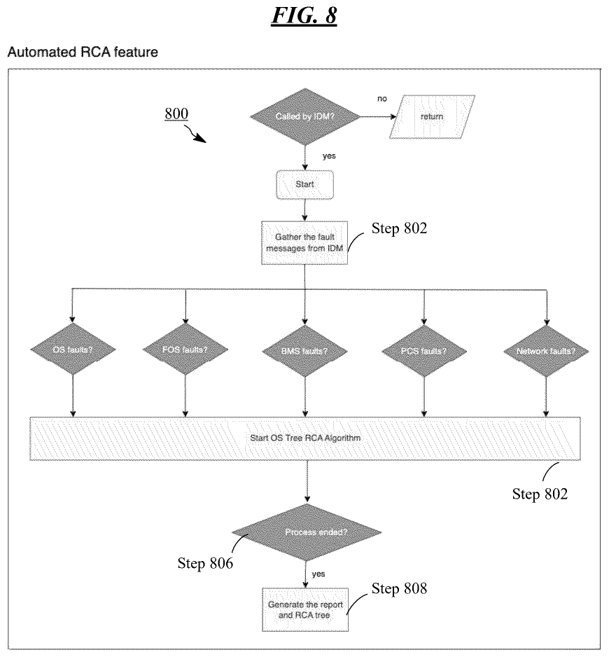

FIG. 5 is a diagram depicting an intelligent diagnostics and monitoring (“IDM”) module 502 in energy storage systems 101. FIG. 6 is a diagram depicting intelligent diagnostics and monitoring (“IDM”) module-logic for the deployment phase of an energy storage system 101. FIG. 7 is a diagram depicting intelligent diagnostics and monitoring (“IDM”) module-logic for the online mode of an energy storage system 101. FIG. 8 is a diagram depicting an automated root cause analysis algorithm and final report generation based on that analysis. Collectively, FIGS. 5-8 depict the intelligent diagnostics and monitoring (“IDM”) logical flow.

The intelligent diagnostics and monitoring (“IDM”) module 502 monitors and automatically diagnoses the energy storage system 101.

The intelligent diagnostics and monitoring (“IDM”) module 502 can run independently on a control hardware or seamlessly integrate with the full operating system (FOS) controls that control the energy storage system 101.

FIG. 5 shows the overall system diagram using an intelligent diagnostics and monitoring (“IDM”) module 502. The IDM module 502 can include a monitoring system developed to monitors FOS control signals, as well as feedback and statuses from a battery management system (BMS), battery, power conversion system (PCS) 104, and meter subsystems. Data from the FOS controls 504, PCS 104, energy storage nodes 105A-N, battery management systems (BMSs) 506, meters 508 collecting measured values relevant to oscillation determinations, such as instant voltage, current, as well as power frequency, instant power, and the rate of change of frequency, switches 510, real-time automation controllers (RTACs) 512, and user interfaces 514, for example, are pushed and pulled via a data acquisition system 516, which feeds the IDM module 502.

The IDM module 502 includes a multi-stage diagnosis algorithm developed to use the control signals and states gathered by the monitoring system to detect an error, a fault, or an abnormality, and warn the user and/or take a remedial action. Part of the multi-stage diagnosis algorithm is a deep predictive diagnostic algorithm designed to predict faults and failures before the faults or failures occur. The IDM module 502 further includes an automated troubleshooting algorithm developed to find the root cause of the faults and failure diagnosed by the diagnosis algorithm, and troubleshoot the energy storage system 101 when errors, faults, or abnormalities are detected. The final output of the IDM module 502 can be, for example, a warning message about the energy storage system 101, and/or an automated report based on the automated troubleshooting algorithm which can describe the fault or failure and provide an automated root cause analysis.

The IDM module 502 can include a deployment submodule and an operation submodule.

In certain embodiments, the deployment submodule can be an additional built-in software module that is separate from the IDM module 502.

The operation submodule of the IDM module 502 is configured to run in real time to perform normal diagnostics and deep diagnostics. The normal diagnostics detects clear or unambiguous faults and failures, or system-level anomalies. The normal diagnostics can detect shallow errors, faults, or abnormalities based on the monitored control signals from the energy storage system 101. The “shallow” errors, faults, or abnormalities can be clear or unambiguous errors, faults, failures, or abnormalities, sometimes referred to as surface-level, or near-surface-level, errors, faults, or abnormalities, for example, that can be detected by the normal diagnostics. For example, the shallow errors can be minor deviations in system performance, such as slight discrepancies in voltage readings, small timing inconsistencies, or non-critical variances in control signals that do not immediately affect overall system functionality. The shallow faults can be significant disruptions in system operations caused by component malfunctions, such as sensor failures, communication breakdowns, or faulty signals between system components, for example, potentially leading to performance degradation or system shutdown. The shallow abnormalities can be irregular system behaviors that deviate from expected patterns, such as unusual temperature fluctuations or atypical charge/discharge cycles, for example, which may indicate emerging issues that may not necessarily result in immediate system failure. The normal diagnostics can also detect system-level or low-level errors, faults, or abnormalities based on monitoring components of the energy storage system 101. The system-level or low-level errors, faults, or abnormalities may include, but are not limited to, the surface-level or “shallow” errors, faults, or abnormalities.

The deep diagnostics is configured to predict faults and failures before the faults or failures occur. For example, a deep diagnostic algorithm can be configured to detect, check, and confirm errors, faults, or abnormalities over multiple data points of the energy storage system 101, and predict a condition that is likely to result in a failure.

The deployment submodule of the IDM module 502 is configured to operate in two modes: a logic state level and in an online level.

First, in the logic state level, the energy storage system 101 is powered on, but is not connected to the electrical application 103 (e.g., grid or customer load). This feature is applicable for the deployment phase of energy storage system 101 projects. In this mode, controls are deployed and logic power is on. Other subsystems may also be powered on and communicate with the controls. In the logic state level, the deployment submodule of the IDM module 502 is configured to check statuses, logs, and signals for abnormalities, interconnected issues, compatibility between components and sub-components, and failures. The logic state level can reduce the complex and time consuming manual troubleshooting.

Second, in the online level, the energy storage system 101 is in operation and connected to the electrical application 103. In the online level, the deployment submodule of the IDM module 502 runs in real time to perform automatic tests and analyze responses for abnormalities and failures.

FIG. 6 illustrates a process flow 600 of an algorithm for the logic mode of the IDM module 502. A user interface (UI) 514 (see FIG. 5) of the operating system (FOS) is configured to enable or disable the logic mode of the IDM module 502. If enabled, the logic mode starts, the IDM module 502 gathers data (e.g., control signals from the energy storage system 101) (step 602), compares the gathered data with the expected or predetermined values and ranges 117A-N(FIG. 4) of the control signals saved in the memory of the control system 115 or the control subsystem 110, and detects errors, faults, or abnormalities, based on the results of the comparison (step 604). If no errors, faults, or abnormalities are detected (step 604, path No), the IDM module 502 generates a report (step 606) and the process 600 ends. If errors, faults, or abnormalities are detected (step 604, path Yes), the IDM module 502 starts the root-cause analysis (RCA) algorithm of FIG. 8, which will issue a report back to the FOS for a user to view via the UI 514. Details of the RCA algorithm of FIG. 8 are described further below.

FIG. 7 illustrates a process flow 700 of an algorithm for the online mode of the IDM module 502. A user interface (UI) 514 (see FIG. 5) of the operating system (FOS) is configured to enable or disable the online mode of the IDM module 502. If enabled, the online mode starts. The online mode first gathers data (e.g., control signals from the energy storage system 101) (step 702), then enters a multi-stage diagnostic process. The first stage of the multi-stage diagnostic process is a shallow analysis of the data (step 704). The shallow analysis of the data detects “shallow” errors, faults, or abnormalities, such as clear or unambiguous faults and failures, for example, detected by the normal diagnostics, as discussed above.

If abnormalities are found (step 704, path Yes), the IDM module 502 starts the RCA algorithm of FIG. 8 (step 706). If no abnormalities are found (step 704, path No), the IDM module 502 starts a predictive deep diagnostic algorithm (step 708). The deep diagnostic algorithm is predictive in the sense that it performs checks and balances over multiple data points of the energy storage system 101 and predicts a condition, in the future, that is likely to result in a failure. If abnormalities are detected after running the deep diagnostic algorithm (step 710, path Yes), in step 712, the process 700 stops and the IDM module 502 starts the RCA algorithm of FIG. 8. Otherwise, if no abnormalities are detected after running the deep diagnostic algorithm (step 710, path No), in step 714, the IDM module 502 generates a full report and reports a “green” (e.g., free of faults or abnormalities) nominal status of the energy storage system 101.

FIG. 8 illustrates a flow 800 of an automated troubleshooting algorithm and report generation. Once called, the troubleshooting algorithm gathers the fault messages from the IDM module 502 (step 802). If an Operating System (OS) fault, FOS fault, BMS fault, PCS fault, network fault, or another fault is found in the fault messages, the IDM module 502 executes an OS tree RCA algorithm to determine the root cause of the faults (step 804). The OS tree RCA algorithm can be a separate component in the same set of algorithm of FIG. 8, such as a proprietary operating system that splits control signals between different components, for example. Once that OS tree RCA algorithm is completed (step 806, path Yes), a report including the RCA tree is sent to the FOS UI for a user to examine and potentially plan a service task for a service team (step 808). The service task for the service team can include, but is not limited to, troubleshooting the energy storage system 101 when errors, faults, or abnormalities are detected, for example. The troubleshooting can include, but is not limited to, further analysis and investigation to detect whether any of the components of the energy storage system 101 are not operating properly, checking if any software may have changed or may have been tempered with (e.g., security breach), updating software or firmware, etc.

In the examples above, the energy system 102, energy application 103, power conversion system 104, energy storage nodes 105A-N, control subsystem 110, control system 115, etc. can each include a processor. As used herein, a processor 312, 352 is a hardware circuit having elements structured and arranged to perform one or more processing functions, typically various data processing functions. Although discrete logic components could be used, the examples utilize components forming a programmable central processing unit (CPU). A processor 312, 352 for example includes or is part of one or more integrated circuit (IC) chips incorporating the electronic elements to perform the functions of the CPU. The processors 312, 352 for example, may be based on any known or available microprocessor architecture, such as a Reduced Instruction Set Computing (RISC) using an ARM architecture. Of course, other processor circuitry may be used to form the CPU or processor hardware in. The illustrated examples of the processors 312, 352 can include one microprocessor or a multi-processor architecture. A digital signal processor (DSP) or field-programmable gate array (FPGA) could be suitable replacements for the processors 312, 352, but may consume more power with added complexity.

The applicable processor 312, 352 executes programming or instructions to configure the energy system 102, energy application 103, power conversion system 104, energy storage nodes 105A-N, control subsystem 110, control system 115, etc. to perform various operations. For example, such operations may include various general operations (e.g., a clock function, recording and logging operational status and/or failure information) as well as various system-specific operations (e.g., daylighting and/or energy management) functions. Although a processor 312, 352 may be configured by use of hardwired logic, typical processors are general processing circuits configured by execution of programming, e.g., instructions and any associated setting data from the memories 313, 353 shown or from other included storage media and/or received from remote storage media.

In the examples above, the energy system 102, energy application 103, power conversion system 104, energy storage nodes 105A-N, control subsystem 110, control system 115, etc. each include a memory. The memory 313, 353 may include a flash memory (non-volatile or persistent storage), a read-only memory (ROM), and a random access memory (RAM) (volatile storage). The RAM serves as short term storage for instructions and data being handled by the processors 312, 352 e.g., as a working data processing memory. The flash memory typically provides longer term storage.

Of course, other storage devices or configurations may be added to or substituted for those in the example. Such other storage devices may be implemented using any type of storage medium having computer or processor readable instructions or programming stored therein and may include, for example, any or all of the tangible memory of the computers, processors or the like, or associated modules.

Hence, a machine-readable medium or a computer-readable medium may take many forms of tangible storage medium. Non-volatile storage media include, for example, optical or magnetic disks, such as any of the storage devices in any computer(s) or the like, such as may be used to implement the client device, media gateway, transcoder, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards, paper tape, any other physical storage medium with patterns of holes, a RAM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

According to exemplary embodiments of the present disclosure the one or more processors and control circuits can include one or more of any known general purpose processor or integrated circuit such as a central processing unit (CPU), microprocessor, field programmable gate array (FPGA), Application Specific Integrated Circuit (ASIC), Digital Signal Processor (DSP), or other suitable programmable processing or computing device or circuit as desired that is specially programmed to perform operations for achieving the results of the exemplar embodiments described herein. The processor(s) can be configured to include and perform features of the exemplary embodiments of the present disclosure, such as the battery condition aware control protocol 400 and the power balancing control programming 330A-B. The features can be performed through program code encoded or recorded on the processor(s), or stored in a non-volatile memory device, such as Read-Only Memory (ROM), erasable programmable read-only memory (EPROM), or other suitable memory device or circuit as desired. Accordingly, such computer programs can represent controllers of the computing device.

In another exemplary embodiment, the program code, such as the battery condition aware control protocol 400 and the power balancing control programming 330A-B, can be provided in a computer program product having a non-transitory computer readable medium, such as Magnetic Storage Media (e.g. hard disks, floppy discs, or magnetic tape), optical media (e.g., any type of compact disc (CD), or any type of digital video disc (DVD), or other compatible non-volatile memory device as desired) and downloaded to the processor(s) for execution as desired, when the non-transitory computer readable medium is placed in communicable contact with the processor(s).

The one or more processors 312, 352 can be included in a computing system that is configured with components such as memory, a hard drive, an input/output (I/O) interface, a communication interface, a display and any other suitable component as desired. The exemplary computing device can also include a communications interface. The communications interface can be configured to allow software and data to be transferred between the computing device and external devices. Exemplary communications interfaces can include a modem, a network interface (e.g., an Ethernet card), a communications port, a PCMCIA slot and card, or any other suitable network communication interface as desired. Software and data transferred via the communications interface can be in the form of signals, which can be electronic, electromagnetic, optical, or other signals as will be apparent to persons having skill in the relevant art. The signals can travel via a communications path, which can be configured to carry the signals and can be implemented using wire, cable, fiber optics, a phone line, a cellular phone link, a radio frequency link, or any other suitable communication link as desired.

Where the present disclosure is implemented using programming or software, including but not limited to the intelligent diagnostics and monitoring (“IDM”) module control programming 330A, the root-cause analysis (“RCA”) control programming 340A, the deep diagnostic control programming 350A, for example, the programming or software can be stored in a computer program product or non-transitory computer readable medium and loaded into the computing device using a removable storage drive or communications interface. In an exemplary embodiment, any computing device, such as control system 115 and control subsystem 110, disclosed herein can also include a display interface that outputs display signals to a display unit, e.g., LCD screen, plasma screen, LED screen, DLP screen, CRT screen, or any other suitable graphical interface as desired.

It will be understood that the terms and expressions used herein have the ordinary meaning as is accorded to such terms and expressions with respect to their corresponding respective areas of inquiry and study except where specific meanings have otherwise been set forth herein. Relational terms such as first and second, or evident and alternative, and the like may be used solely to distinguish one entity or action from another without necessarily requiring or implying any actual such relationship or order between such entities or actions. The terms “comprises,” “comprising,” “includes,” “including,” or any other variation thereof, are intended to cover a non-exclusive inclusion, such that a process, method, article, or apparatus that comprises or includes a list of elements or steps does not include only those elements or steps but may include other elements or steps not expressly listed or inherent to such process, method, article, or apparatus. An element preceded by “a” or “an” does not, without further constraints, preclude the existence of additional identical elements in the process, method, article, or apparatus that comprises the element.

Unless otherwise stated, any and all measurements, values, ratings, positions, magnitudes, sizes, angles, and other specifications that are set forth in this specification, including in the claims that follow, are approximate, not exact. Such amounts are intended to have a reasonable range that is consistent with the functions to which they relate and with what is customary in the art to which they pertain. For example, unless expressly stated otherwise, a parameter value or the like may vary by as much as ±5% or as much as ±10% from the stated amount. The terms “approximately” and “substantially” mean that the parameter value or the like varies up to ±10% from the stated amount or position.

In addition, in the foregoing Detailed Description, it can be seen that various features are grouped together in various examples for the purpose of streamlining the disclosure. This method of disclosure is not to be interpreted as reflecting an intention that the claimed examples require more features than are expressly recited in each claim. Rather, as the following claims reflect, the subject matter to be protected lies in less than all features of any single disclosed example. Thus, the following claims are hereby incorporated into the Detailed Description, with each claim standing on its own as a separately claimed subject matter.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present concepts.

The scope of protection is limited solely by the claims that now follow. That scope is intended and should be interpreted to be as broad as is consistent with the ordinary meaning of the language that is used in the claims when interpreted in light of this specification and the prosecution history that follows and to encompass all structural and functional equivalents. Notwithstanding, none of the claims are intended to embrace subject matter that fails to satisfy the requirement of Sections 101, 102, or 103 of the Patent Act, nor should they be interpreted in such a way. Any unintended embracement of such subject matter is hereby disclaimed.

Except as stated immediately above, nothing that has been stated or illustrated is intended or should be interpreted to cause a dedication of any component, step, feature, object, benefit, advantage, or equivalent to the public, regardless of whether it is or is not recited in the claims.

What is claimed is:

1. A system, comprising:
an energy storage system, including a plurality of energy storage nodes; and
an intelligent diagnostics and monitoring (“IDM”) module coupled to the energy storage system, the IDM module comprising a processor, the IDM module being configured to:
monitor control signals of the energy storage system; and
enter a multi-stage diagnostic process including:
detecting shallow errors, faults, or abnormalities based on the monitored control signals;
starting a root-cause analysis (RCA) algorithm when shallow errors, faults, or abnormalities are detected;
starting a deep diagnostic algorithm when no shallow errors, faults, or abnormalities are detected;
after starting the deep diagnostic algorithm, detecting errors, faults, or abnormalities based on the monitored control signals; and
troubleshoot the energy storage system when errors, faults, or abnormalities are detected.

2. The system of claim 1, wherein the deep diagnostic algorithm is configured to predict faults and failures before the faults or failures occur.

3. The system of claim 1, wherein the deep diagnostic algorithm is configured to detect, check, and confirm errors, faults, or abnormalities over multiple data points and predict a condition that is likely to result in a failure.

4. The system of claim 2, further comprising an automated troubleshooting algorithm configured to find a root cause of the faults and failures diagnosed by the deep diagnosis algorithm.

5. The system of claim 4, wherein the IDM module is further configured to generate an automated report based on the automated troubleshooting algorithm and provide an automated root cause analysis.

6. The system of claim 4, wherein the automated troubleshooting algorithm is configured to gather fault messages from the IDM module, and if fault is found in the fault messages, execute an OS tree RCA algorithm to determine the root cause of the faults.

7. The system of claim 1, wherein the IDM module comprises a deployment submodule and an operation submodule.

8. The system of claim 7, wherein the operation submodule is configured to run in real time to perform normal diagnostics and deep diagnostics.

9. The system of claim 8, wherein the normal diagnostics detects clear or unambiguous faults and failures, or system-level anomalies.

10. The system of claim 7, wherein the deployment submodule is configured to operate in a logic state level and in an online level.

11. The system of claim 10, wherein in the logic state level, the energy storage system is disconnected from an electrical application and in the online level, the energy storage system is connected to the electrical application.

12. The system of claim 10, wherein in the logic state level, the deployment submodule is configured to check statuses, logs, and signals for abnormalities, interconnected issues, compatibility between components and sub-components, and failures.

13. The system of claim 10, wherein in the online level, the deployment submodule is configured to run automatic tests and analyze responses for abnormalities and failures.

14. The system of claim 1, wherein the IDM module is configured to monitor and automatically diagnose the energy storage system.

15. The system of claim 1, wherein the IDM module is configured to monitor full operating system (FOS) control signals, feedback and statuses from the energy storage system, at least one power conversion system, and meter subsystems.

16. The system of claim 1, wherein the IDM module is configured to run independently on a control hardware or seamlessly integrate with a full operating system (FOS) controls that control the energy storage system.

17. The system of claim 1, further comprising a user interface (UI) configured to enable or disable the IDM module.

18. The system of claim 1, wherein the IDM module is further configured to generate a report and alert a service team tasked with correcting failures and faults.

19. A method, comprising:
detecting shallow abnormalities of an energy storage system;
starting a root-cause analysis (RCA) algorithm when shallow abnormalities are detected;
starting a deep diagnostic algorithm when no shallow abnormalities are detected;
after starting the deep diagnostic algorithm, detecting abnormalities based on the monitored control signals; and
troubleshooting the energy storage system when abnormalities are detected.

20. A non-transitory computer-readable medium, comprising an intelligent diagnostics and monitoring (“IDM”) module, wherein execution of the IDM module by one or more processors configures one or more computing devices to:
detect shallow abnormalities of an energy storage system;
start a root-cause analysis (RCA) algorithm when shallow abnormalities are detected;
start a deep diagnostic algorithm when no shallow abnormalities are detected;
after starting the deep diagnostic algorithm, detect abnormalities based on the monitored control signals; and
troubleshoot the energy storage system when abnormalities are detected.
